(19) United States
(12) Patent Application Publication
(10) Pub. No.: US 2024/0218500 A1
(43) Pub. Date: Jul. 4, 2024

(54) METHODS FOR SELECTIVELY FORMING AND UTILIZING A PASSIVATION LAYER ON A SUBSTRATE AND RELATED STRUCTURES INCLUDING A PASSIVATION LAYER

(71) Applicant: ASM IP Holding B.V., Almere (NL)

(72) Inventors: Anirudhan Chandrasekaran, Scottsdale, AZ (US); Daniele Chiappe, Freiburg (DE); Eva E. Tois, Espoo, FL (US); Viraj Madhiwala, Heverlee (BE); Andrea Illiberi, Leuven (BE); Shaoren Deng, Ghent (BE)

(21) Appl. No.: 18/397,722

(22) Filed: Dec. 27, 2023

Related U.S. Application Data
(60) Provisional application No. 63/477,765, filed on Dec. 29, 2022.

(51) Int. Cl. C23C 16/04; C23C 16/18

(52) U.S. Cl. CPC C23C 16/04; C23C 16/18

(57) ABSTRACT

Methods for forming selective passivation layers on a first dielectric surface relative to a second metallic surface are disclosed. Methods for utilizing selective passivation layers for depositing target films as also disclosed. Exemplary structures that include selective passivation layers are further disclosed.

### CROSS-REFERENCE TO RELATED APPLICATION(S)

This application claims the benefit of U.S. Provisional Application 63/477,765 filed on Dec. 29, 2022, the entire contents of which are incorporated herein by reference.

### FIELD OF INVENTION

The present disclosure generally relates to the field of semiconductor processing methods and related structures, and to the field of device and integrated circuit manufacture. More particularly, the present disclosure relates to methods for selectively forming and utilizing passivation layers, as well as structures including such passivation layers.

### BACKGROUND OF THE DISCLOSURE

In some applications, it may be desirable to deposit a passivation layer only on certain areas of a substrate. Typically, such discriminating results are achieved by depositing a continuous passivation layer and subsequently patterning the passivation layer using lithography and etch steps. Such lithography and etch processes may be time consuming and expensive, and do not offer the precision required for many applications.

A possible solution is the use of selective deposition processes, whereby a passivation layer is preferentially deposited only in the desired areas thereby eliminating the need for subsequent patterning steps. Selective deposition processes may take a number of forms, including, but not limited to, selective dielectric deposition on dielectric surfaces (DoD), selective dielectric deposition on metallic surfaces (DOM), selective metal deposition on dielectric surfaces (MoD) and selective metal deposition on metallic surfaces (MoM).

Selective deposition of passivation layers that can enable MoM or DoM type processes and are of interest for providing simplified methods for depositing a target film (e.g., a dielectric film or a metallic film) over metallic surfaces without the need for complex patterning and etch steps. However, the surface properties of metallic surfaces can negatively impact selective deposition of passivation layers. Accordingly, improved methods are desired for the selective deposition of passivation layers on dielectric surfaces relative to metallic surfaces.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

In particular the present disclosure includes methods for selectively forming a passivation layer on a substrate, the methods comprising, seating a substrate including a first dielectric surface and a second metallic surface within a reaction chamber, and selectively depositing a passivation layer on the first dielectric surface relative to the second metallic surface by performing multiple deposition cycles of a cyclical deposition process in which the substrate is alternately and sequentially contacted with a first vapor phase organic precursor and a second vapor phase organic precursor for forming the passivation layer. The methods can further include, wherein one or more of the deposition cycles includes an additional step of contacting the substrate with an additional vapor phase reactant comprising a vapor phase reducing agent, or a vapor phase etchant.

In some embodiments, the cyclical deposition process is a plasma-free thermal molecular layer cyclical deposition process.

In some embodiments, the first vapor phase organic precursor comprises a diamine, the second vapor phase organic precursor comprises a dianyhydride, and the passivation layer comprises a polyimide.

In some embodiments, the one or more deposition cycles including the additional step are performed in a sequence comprising, firstly contacting the substrate with the additional vapor phase reactant comprising a vapor phase reducing agent, or a vapor phase etchant, secondly contacting the substrate with first vapor phase organic precursor, and thirdly contacting the substrate with the second vapor phase organic precursor.

In some embodiments, the initial deposition cycle includes the additional step of contacting the substrate with the additional vapor phase reactant, wherein the additional step is performed prior to contacting the substrate with the first vapor phase organic precursor and prior to contacting the substrate with the second vapor phase organic precursor.

In some embodiments, every deposition cycle includes the additional step of contacting the substrate with the additional vapor phase reactant.

In some embodiments, the one or more deposition cycles include the additional step and the additional step is performed prior to contacting the substrate with the first vapor phase organic precursor and prior to contacting the substrate with the second vapor phase organic precursor.

In some embodiments, the one or more deposition cycles include the additional step and the additional step is performed after contacting the substrate the second vapor phase organic precursor.

In some embodiments, the vapor phase reducing agent is selected from the group consisting of alcohols, β-diketones, carboxylic acids, amines, aldehydes, boranes, forming gas (H₂+N₂), hydrazine (N₂H₄), hydrazine derivatives, molecular hydrogen (H₂), and atomic hydrogen (H).

In some embodiments, the vapor phase etchant is selected from the group consisting of acetic acid, and hexafluoroacetylacetone (H(hfac))

In some embodiments, the first metallic surface comprises a copper oxide (CuOₓ) surface and contacting the copper oxide (CuOₓ) surface with the additional vapor phase reactant at least partially removes the copper oxide (CuOₓ) surface.

In some embodiments, the first metallic surface further comprises an organic residue and contacting the organic residue with the additional vapor phase reactant at least partially removes the organic residue.

The present disclosure also further methods for selectively forming and utilizing a passivation layer on a substrate, the methods comprising, seating a substrate including a first dielectric surface and a second metallic surface within a reaction chamber, and selectively depositing an organic passivation layer on the first dielectric surface relative to the second metallic surface by performing a plurality of deposition cycles of a plasma-free thermal molecular layer cyclical deposition process in which the substrate is alternately and sequentially contacted with a first vapor phase organic precursor, and a second vapor phase organic precursor, wherein one or more of the deposition cycles includes an additional step of contacting the substrate with an additional vapor phase reactant comprising a vapor phase reducing agent, or a vapor phase etchant. The methods can further include, depositing a target film from vapor phase reactants on the second metallic surface.

In some embodiments, the organic passivation layer is deposited on the first dielectric surface relative to the second metallic surface with a selectivity above 50%.

In some embodiments, the first vapor phase organic precursor comprises a diamine, the second vapor phase organic precursor comprises a dianyhydride, and the passivation layer comprises a polyimide.

In some embodiments, the one or more deposition cycles including the additional step are performed in a sequence comprising, firstly contacting the substrate with the additional vapor phase reactant comprising a vapor phase reducing agent, or a vapor phase etchant, secondly contacting the substrate with first vapor phase organic precursor, and thirdly contacting the substrate with the second vapor phase organic precursor

In some embodiments, the target film is deposited by performing a plurality of deposition cycles of a plasma-free thermal cyclical deposition process in which the substrate is alternately and sequentially contacted with a first vapor phase reactant, and a second vapor phase reactant.

In some embodiments, the target film comprises a dielectric film or a metallic film.

The present disclosure also includes structures formed according to the methods disclosed herein.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrates an exemplary method for selectively forming a passivation layer on a first dielectric surface relative to a second metallic surface on a substrate in accordance with at least one embodiment of the present disclosure;

FIG. 2 illustrates an exemplary method for forming a target film on a metallic surface in accordance with at least one embodiment of the present disclosure; and

FIGS. 3A-D illustrates cross-sectional views of structures formed in accordance with at least one embodiment of the present disclosure;

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices, and apparatus provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods for selectively forming passivation layers suitable for a variety of applications. Exemplary methods can be used, for example, for the selective deposition of a dielectric target film on metallic surfaces, or the selective deposition of a metal target film on metallics surfaces. However, unless noted otherwise, the invention is not necessarily limited to such examples.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include helium, argon, and any combination thereof. In some cases, an inert gas can include nitrogen and/or hydrogen.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e. ceramic fibers or polymer fibers). Continuous substrates may also comprise carriers or sheets upon which non-continuous substrates are mounted.

As used herein, the term “film” and/or “layer” can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, a “structure” can be or include a substrate as described herein. Structures can include one or more layers overlying or within the substrate, such as one or more layers formed according to a method as described herein. Full devices or partial device portions can be included within or on structures.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), molecular layer deposition (MLD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each deposition cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more deposition cycles, e.g., during each step of each cycle, to remove any excess precursor from the process chamber and/or remove any excess reactant and/or reaction byproducts from the reaction chamber.

As used herein, the term “molecular layer deposition” (MLD) may refer to a vapor deposition process in which deposition cycles, preferably a plurality of consecutive deposition cycles, are conducted in a process chamber. Typically, during each cycle an organic precursor is chemisorbed to a deposition surface (e.g., a substrate surface or a previously deposited underlying surface such as material from a previous MLD cycle), typically forming a single molecular layer that does not readily react with additional organic precursor (i.e., a self-limiting reaction). Thereafter, if necessary, another precursor (e.g., another organic precursor) may subsequently be introduced into the process chamber for use in forming the desired organic material on the deposition surface. Further, purging steps may also be utilized during each cycle to remove excess organic precursor from the process chamber and/or remove reaction byproducts from the process chamber after formation of the desired organic material.

As used herein, the term “metallic surface” may refer to surfaces including a metallic component, including, but not limited to, metal surfaces, metal oxide surfaces, metal silicide surfaces, metal nitride surfaces, metal carbide surfaces, and mixtures thereof. The term “metallic surface” may can also include a surface of a native oxide of a metallic material.

As used herein, the term “dielectric surface” may refer a surface of dielectric material, including, but not limited to, silicon containing dielectric materials, such as, for example, silicon oxides, silicon nitrides, silicon oxynitrides, silicon oxycarbides, and mixtures thereof. In addition, the term “dielectric surface” may also refer to a surface of metal oxide material, or metal nitride material, or low dielectric constant material (a low-k material), or high dielectric constant material (a high-k material).

As used herein, the term “comprising” indicates that certain features are included, but that it does not exclude the presence of other features, as long as they do not render the claim unworkable. In some embodiments, the term “comprising” includes “consisting.”

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. This notwithstanding, the chemical compound, substance, or composition of matter may, in some embodiments, comprise other components as trace elements or impurities, apart from the components that are listed.

A number of example materials are given throughout the embodiments of the current disclosure, it should be noted that the chemical formulas given for each of the example materials should not be construed as limiting and that the non-limiting example materials given should not be limited by a given example stoichiometry.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

The embodiments of the present disclosure include methods for the selective deposition of passivation layers on a first dielectric surface of a substrate relative to a second metallic surface on a substrate by performing multiple deposition cycles of a cyclical deposition process, wherein one or more of the deposition cycles includes an additional step of contacting the substrate, and particularly contacting the second metallic surfaces, with a vapor phase reducing agent, or a vapor phase etchant. The cyclical deposition processes for selectively forming the passivation layers of the present disclosure are plasma-free processes, i.e., the cyclical deposition processes do not employ reactive species generated by a plasma. For example, plasma-based processes, and the reactive species generated by such processes, can have a detrimental effect on the passivation layer as it is being deposited and therefore plasma-free cyclical deposition processes can be advantageous in the methods of the present disclosure.

After selective formation of the passivation layer over the dielectric surfaces, further processes may be utilized to deposit a target film on the metallic surfaces relative to the passivation layer, i.e., a greater thickness of the target film is deposited on the metallic surfaces relative to the thickness of the target film deposited on the passivation layer. Any unwanted target film disposed over the passivation layer may be removed by an etch process. Following the selective deposition of the target film over the metallic surfaces of the substrate the remaining passivation layer may be selectively removed while maintaining at least a portion of the target film disposed over the metallic surfaces.

Selectivity of deposition on surface A relative to surface B can be given as a percentage calculated by [(deposition on surface A)−(deposition on surface B)]/(deposition on the surface A). Deposition can be measured in any of a variety of ways. For example, deposition may be given as the measured thickness of the deposited material, or may be given as the measured amount of material deposited. In embodiments described herein, selective deposition of a passivation layer can be conducted on a first dielectric surface (A) relative to a second metallic surface (B). Subsequently, a target film may be selectively deposited on the second metallic surface (A) relative to the passivation film (B).

In some embodiments, selectivity for the selective deposition of the passivation layer on the first dielectric surface (relative to the second metallic surface) is greater than about 10%, or greater than about 50%, or greater than about 75%, or greater than about 85%, or greater than about 90%, or greater than about 93%, or greater than about 95%, or greater than about 98%, or greater than about 99%, or even greater than about 99.5%.

In some embodiments, deposition only occurs on the first surface and does not occur on the second surface. In some embodiments, deposition on surface A of the substrate relative to surface B of the substrate is at least about 80% selective, which may be selective enough for some particular applications. In some embodiments, the deposition on the surface A of the substrate relative to surface B of the substrate is at least about 50% selective, which may be selective enough for some particular applications. In some embodiments the deposition on surface A of the substrate relative to the surface B of the substrate is at least about 10% selective, which may be selective enough for some particular applications. The skilled artisan will appreciate that a partially selective process can result in a fully selective structure by a post-deposition etch that removes all of the deposited material from over surface B without removing the entirety of the deposited material from over surface A.

The embodiments of the present disclosure include methods for selectively forming and utilizing a passivation layer. In particular, the methods of the present disclosure include methods for selectively depositing passivation layers by plasma-free cyclical deposition processes. In some embodiments, the cyclical deposition processes of the present disclosure may comprise, plasma-free thermal molecular layer cyclical deposition processes. The deposition cycles employed in the present disclosure can include additional steps beyond those of supplying the organic precursors to the substrate for forming the passivation layer. In particular, the additional steps of the present disclosure include contacting the substrate, and particular the metallic surfaces on the substrate, with additional vapor phase reactants which are employed for removing surface oxides, contaminants, impurities, organic residues, and other unwanted surface materials, which could otherwise have a detrimental effect on the formation of the passivation layer and the selectivity of the deposition process.

Methods for selectively forming a passivation layer by vapor deposition techniques are disclosed and described in U.S. Pat. No. 10,373,820, filed on Jun. 1, 2016 (hereinafter the “'769 patent”), the entire disclosure of which is incorporated herein by reference for all purposes. Certain methods for forming a passivation layer are disclosed in the '769 patent and therefore the present disclosure summarizes such disclosure when needed in the interest of brevity and describes in detail the additional and novel methods employed for improved methods for selectively forming passivation layers and utilizing said passivation layers.

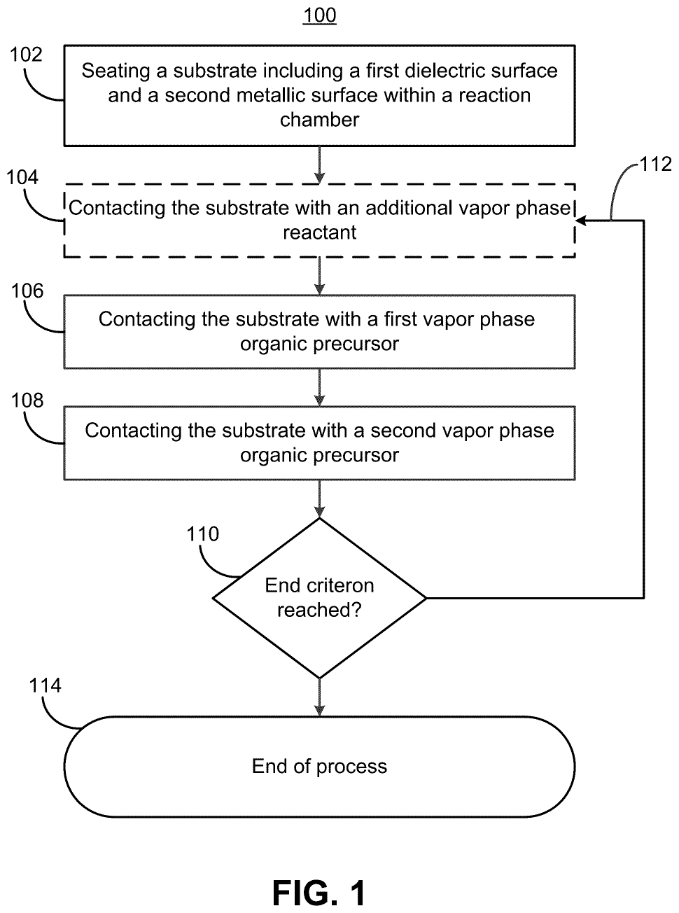

In more detail, FIG. 1 illustrates an exemplary process 100 for selectively forming a passivation layer on a first dielectric surface relative to a second metallic surface. The exemplary process 100 may commence with the process step 102 comprising, seating a substrate including a first dielectric surface and a second metallic surface within a reaction chamber.

The substrates of the present disclosure may comprise a plurality of first dielectric surfaces and a plurality of second metallic surfaces. For example, the substrate can include dielectric surfaces of low dielectric constant materials, i.e., a low-k material, which may be defined as a material with a dielectric constant less than about 4.0. In some embodiments, the first dielectric surface may comprise a silicon containing surface, such as, for example, a silicon oxide, a silicon nitride, a silicon carbide, a silicon oxynitride, a silicon oxycarbide, or mixtures thereof. In some embodiments, the first dielectric surface may comprise a metal oxide, a metal nitride, a semi-metal oxide, or a semi-metal nitride.

In some embodiments, the second metallic surface can include an elemental metal, such as, for example, copper (Cu), molybdenum (Mo), cobalt (Co), nickel (Ni), or tungsten (W). In some embodiments, the metallic surface may comprise a transition metal, such as, for example, titanium (Ti), vanadium (V), chromium (Cr), manganese (Mn), niobium (Nb), molybdenum (Mo), ruthenium (Ru), rhodium (Rh), palladium (Pd), silver (Ag), gold (Au), hafnium (Hf), tantalum (Ta), tungsten (W), rhenium (Re), osmium (Os), iridium (Ir), or platinum (Pt). In some embodiments, the second metallic surface can include a native metallic oxide, contaminants, residues, and other undesirable surface materials.

The process step 102 of exemplary process 100 may further comprise, seating the substrate into a suitable reaction chamber. The reaction chamber may be configured for performing all, or a portion, of the remaining process steps of exemplary process 100. Reactors and associated reaction chamber(s) capable of the selective formation of passivation layers according to the embodiments of the present disclosure may include reaction chambers configured to perform plasma-free cyclical deposition processes, such as, for example reaction chambers configured to perform atomic/molecular layer deposition (ALD/MLD) processes, as well as reaction chambers configured to perform cyclical chemical vapor deposition (CCVD) processes.

Once the substrate is seated within the reaction chamber it may be heated to a suitable deposition temperature. For example, the substrate may be heated to a deposition temperature greater than 0° C., or less than 500° C., or less than 400° C., or less than 300° C., or less 200° C., or less than 100° C., or less than 50° C., or less than 20° C., or between 20° C. and 500° C.

In addition to controlling the deposition temperature, the pressure in the reaction chamber may also be regulated to enable selective deposition of a passivation layer. For example, in some embodiments of the disclosure, the pressure within the reaction chamber may be less than 760 Torr, or between 0.1 Torr and 10 Torr, or between 0.5 Torr and 5 Torr, or between 1 Torr to 4 Torr.

Once the substrate is at the desired deposition temperature and the pressure in the reaction chamber has been regulated as desired, the exemplary process 100 (FIG. 1) may continue by way of, selectively depositing a passivation layer on a first dielectric surface relative to a second metallic surface by performing multiple deposition cycles of a cyclical deposition process in which the substrate is alternately and sequentially contacted with a first vapor phase organic precursor and a second vapor phase organic precursor for forming a passivation layer, and wherein one or more of the deposition cycles includes an additional step of contacting the substrate with an additional vapor phase reactant comprising a vapor phase reducing agent, or a vapor phase etchant.

In more detail and with continue reference to exemplary process 100 (FIG. 1), the deposition cycles of the present disclosure can include contacting the substrate with a first vapor phase organic precursor (step 106) and contacting the substrate with a second vapor phase organic precursor (step 108), as well as in one or more of the deposition cycles, contacting the substrate with an additional vapor phase reactant comprising a vapor phase reducing agent, or a vapor phase etchant (step 104). The process steps of contacting of the substrate with the first and second vapor phase organic precursors (steps 106 and 108) can be utilized in the deposition of a passivation layer, and in particular embodiments the deposition of an organic passivation layer. In some embodiments, the organic passivation layer can comprise a polyimide.

The additional process step (step 104) comprising, contacting the substrate with an additional vapor phase reactant comprising a vapor phase reducing agent, or vapor phase etchant is illustrated by a dashed line in exemplary process 100 (FIG. 1) as this additional process step may not necessarily be performed during each and every deposition cycle. However, the additional process step 104 can be performed one or more times during the formation of the selective passivation layer.

In more detail, the additional process step (step 104) which comprises, contacting the substrate with an additional vapor phase reactant comprising a vapor phase reducing agent, or a vapor phase etchant can be employed during one or more deposition cycles to remove surface oxides, contaminants, impurities, organic residues, and other unwanted surface materials, that could otherwise impact the quality of the passivation layer and/or impact the selectivity of the cyclical deposition process.

In some embodiments, the additional vapor phase reactant provided to substrate in additional process step 104 can contact the second metallic surface to remove surface oxides contaminants, impurities, organic residues, and other unwanted surface materials from the second metallic surface. In some embodiments, the removal of unwanted materials from the second metallic surface (via additional process step 104) can prevent the initiation of deposition of the passivation layer on the second metallic surface thereby improving selectivity of the process 100.

As a non-limiting example, the second metallic surface on the substrate may include a surface native oxide which could negatively impact process 100 by allowing the initiation of growth of the passivation layer upon the native oxide thereby impacting the selectivity of the selective cyclical deposition process. In such an example, the additional step of contacting the substrate with the additional vapor phase reactant comprising a vapor phase reducing agent, or a vapor phase etchant (step 104) can remove the unwanted native oxide from the second metallic surface and thereby prevent the initialization of deposition of the passivation layer on the second metallic surface.

As a further non-limiting example, after a number of deposition cycles have been performed and the substrate has been repeatably contacted with the first vapor phase organic precursor (step 106), and repeatably contacted with the second vapor phase organic precursor (step 108), the second metallic surface may include an organic residue which could impact the selectivity of the selective cyclical deposition processes of the present disclosure. In such an example, the additional step of contacting the substrate with the additional vapor phase reactant comprising a vapor phase reducing agent, or a vapor phase etchant (step 104) can remove the unwanted organic residue on the second metallic surface and thereby prevent the initialization of deposition of the passivation layer on the second metallic surface.

The additional step of contacting the substrate with an additional vapor phase reactant (step 104) is illustrated in the exemplary process 100 (FIG. 1) as being performed prior to the contacting the substrate with the first vapor phase organic precursor (step 106) and prior to contacting the substrate with the second vapor phase organic precursor (steps 108). However, the additional step of contacting the substrate with an additional vapor phase reactant (step 104) can be performed anywhere within the sequence of the deposition cycle of exemplary process 100, or alternatively can be omitted from a deposition cycle, wherein a deposition can comprise, optionally contacting the substrate with an additional vapor phase reactant (step 104), contacting the substrate with a first vapor phase organic precursor (step 106), and contacting the substrate with a second vapor phase organic precursor (step 108). It should be noted that after each step of the deposition cycle illustrated in exemplary process 100 (i.e., step 104, step 106, and step 108), a purge cycle can be performed to remove excess precursor(s), reactant(s), and any reaction by-products.

In some embodiments of the disclosure, wherein the one or more deposition cycles includes the additional step of contacting the substrate with the additional vapor phase reactant (step 104), the deposition cycle can be performed in a sequence comprising, firstly contacting the substrate with the additional vapor phase reactant comprising a vapor phase reducing agent, or a vapor phase etchant (step 104), secondly contacting the substrate with first vapor phase organic precursor (step 106), and thirdly contacting the substrate with the second vapor phase organic precursor (step 108).

In some embodiments, the initial deposition cycle performed in process 100 can include the additional step of contacting the substrate with the additional vapor phase reactant comprising a vapor phase reducing agent, or a vapor phase etchant (step 104). In such embodiments, the additional step (step 104) can be performed prior to contacting the substrate with the first vapor phase organic (step 106) and prior to contacting the substrate with the second vapor phase organic precursor (step 108). For example, in such embodiments, the initial deposition cycle can include the additional step (step 104) to enable the removal of surface oxides, contaminants, impurities, organic residues, and other unwanted surface materials, prior to introducing the organic precursors utilized for forming the passivation layer, therefore ensuring the passivation layer can be deposited over an initially clean surface, and particular so that the second metallic surface is free of any surface oxides, contaminants, impurities, organic residues, and other unwanted surface materials, which could otherwise negatively impact the selectively of the process 100.

In some embodiments, every deposition cycle performed in exemplary process 100 can include the additional step of contacting the substrate with the additional vapor phase reactant comprising a vapor phase reducing agent, or a vapor phase etchant (step 104).

In some embodiments, wherein the one or more deposition cycles includes the additional step of contacting the substrate with the additional vapor phase reactant (step 104), the additional step (step 104) can be performed prior to contacting the substrate with the first vapor phase organic precursor (step 106) and prior to contacting the substrate with the second vapor phase organic precursor (step 108).

In some embodiments, wherein the one or more deposition cycles includes the additional step of contacting the substrate with the additional vapor phase reactant (step 104), the additional step (step 104) can be performed after contacting the substrate with the second vapor phase organic precursor (step 108).

In some embodiments, the additional vapor phase reactant contacting the substrate during process step 104 may comprise a vapor phase reducing agent selected from the group consisting of alcohols, β-diketones, such as halogenated β-diketones, carboxylic acids, amines, aldehydes, boranes, forming gas (H₂+N₂), hydrazine (N₂H₄), hydrazine derivatives, molecular hydrogen (H₂), and atomic hydrogen (H). Exemplary alcohols that may be suitable for performing the current method include linear and branched C1 to C6 alcohols, including primary alcohols, such as methanol, ethanol, 1-propanol, 1-butanol, 1-pentanol, 1-hexanol and secondary alcohols, such as isopropanol. In some embodiments, tertiary alcohols may be used. Exemplary β-diketones that may be suitable for performing the current method include acetylacetone (H(acac)), dipivaloylmethane (H(thd)) and hexafluoroacetylacetone (H(hfac)).

Exemplary carboxylic acids that may be suitable for performing the current method, include linear and branched C1 to C6 carboxylic acids, including formic acid, acetic acid, propionic acid, butyric acid, isobutyric acid, 2-methylbutyric acid.

Exemplary amines that may be suitable for performing the current method include linear and branched C1 to C6 amines, including primary amines, secondary amines and tertiary amines. For example, tert-butylamine (′Bu)NH₂, diethylamine (Et₂NH) may be used.

Exemplary boranes that may be suitable for performing the current method include borane (BH₃) and derivatives thereof, such as diborane (B₂H₆), borane dimethylamine (BH₃(NHMe₂)).

In some embodiments, the additional vapor phase reactant contacting the substrate during process step 104 may comprise a vapor phase etchant selected from the group consisting of acetic acid, and hexafluoroacetylacetone (H(hfac)).

In some embodiments, the additional vapor phase reactant, may contact the substrate for time period between 0.01 seconds and 200 seconds, or between 0.05 seconds and 100 seconds, or between 0.1 and 50 seconds, or between 0.2 seconds and 25 seconds, between 0.5 second and 10 seconds. In some embodiments, the additional vapor phase reactant, may contact the substrate for time period greater than 1 seconds, or greater than 5 seconds, or greater than 10 seconds, or greater than 30 seconds, or greater 60 seconds, or greater than 120 seconds, or greater 200 seconds, or greater than 300 seconds, or between 1 seconds and 300 seconds. It should be noted that the contact time for the additional vapor phase reactant with the substrate can be dependent on how frequently the additional step (step 104) is included in the cyclical deposition cycle and can also be dependent on the composition of the first dielectric surface and the second metallic surface, as well as the surface oxides, contaminants, impurities, organic residues, and other unwanted surface materials that may be present on the surfaces of the substrate.

Upon contacting the substrate with the additional vapor phase reactant (step 104), the reaction chamber may be purged of any excess reactant and/or reaction by-products.

As a non-limiting example, in some embodiments, the second metallic surface may comprise a copper (Cu) surface and in particular a native copper oxide surface (CuOₓ). In such embodiments, the additional vapor phase reactant introduced in additional step 104 can comprise a vapor phase etchant comprising a β-diketone, such as hexafluoroacetylacetone (H(hfac)) which when introduced into the reaction chamber and contacts the substrate, and particularly contacts the copper oxide (CuOₓ) thereon, can remove the copper oxide (CuOₓ) thereby providing a second metallic surface (in this case copper) which does not promote deposition of the passivation layer thereon. Therefore, in some embodiments, the second metallic surface comprises a copper oxide (CuOₓ) and contacting the copper oxide (CuOₓ) surface with the additional vapor phase reactant (step 104) can at least partially, or completely, remove the copper oxide (CuOₓ) surface.

As a further non-limiting example, in some embodiments, the second metallic surface may include an organic residue as described herein above. In such embodiments, the additional vapor phase reactant introduced in additional step 104 can include a vapor phase reducing agent comprising an alcohol, such as ethanol, for example, which when introduced into the reaction chamber and contacts the substrate, and particularly contacts the organic residue thereon can remove the organic residue and thereby provide a second metallic surface which does not promote deposition of the passivation layer thereon. Therefore, in some embodiments, the second metallic surface further comprises an organic residue and contacting the organic residue with the additional vapor phase reactant at least partially, or completely, removes the organic residue from the second metallic surface.

The exemplary process 100, and particular the deposition cycle of process 100 also includes the steps of, contacting the substrate with a first vapor phase organic precursor (step 106), and contacting the substrate with a second vapor phase organic precursor (step 108). The details relating to the process steps 106 and 108 and the precursors that can be employed in said process steps are described in detail in the '769 patent and are therefore briefly described herein in the interest of brevity.

Therefore, in some embodiments, the exemplary process 100 further comprises, contacting the substrate with a first vapor phase organic precursor (step 106). In some embodiments, the first vapor phase organic precursor can comprise an organic reactant such as a diamine, such as, for example, 1,6-diaminohexane (DAH), or any other monomer with two reactive groups. In some embodiments, the first vapor phase organic precursor may comprise a diamine and may be vaporized to produce a first vapor phase organic precursor comprising a diamine vapor which is transported to the reaction chamber and contacts the substrate.

In some embodiments, the first vapor phase organic precursor, may contact the substrate for time period between 0.01 seconds and 60 seconds, or between 0.05 seconds and 30 seconds, or between 0.1 and 10 seconds, or between 0.2 seconds and 5 seconds. In some embodiments, where batch reactors may be used, exposure periods of greater than 60 seconds may be employed.

Upon contacting the substrate with the first vapor phase organic precursor (step 106), the reaction chamber may be purged of any excess reactant and/or reaction by-products.

The exemplary process 100 can continue with the process step 108 that can comprise, contacting the substrate with a second vapor phase organic precursor. For example, in some embodiments, the second vapor phase organic precursor can comprise an anhydride, such as furan-2,5-dione (maleic acid anhydride) and methods may comprise vaporizing the anhydride and transporting the anhydride vapor to the reaction chamber and contacting the substrate with the anhydride vapor. In some embodiments of the disclosure, the anhydride may comprise a dianhydride, e.g., pyromellitic dianhydride (PMDA), or any other monomer with two reactive groups which will react with the first vapor phase organic precursor.

In some embodiments, the second vapor phase organic precursor, may contact the substrate for time period between 0.01 seconds and 60 seconds, or between 0.05 seconds and 30 seconds, or between 0.1 and 10 seconds, or between 0.2 seconds and 5 seconds. In some embodiments, where batch reactors may be used, exposure periods of greater than 60 seconds may be employed.

Upon contacting the substrate with the second vapor phase organic precursor (step 108), the reaction chamber may be again purged of any excess precursor and/or reaction by-products.

The exemplary process 100 (FIG. 1) may continue via a decision gate 110, wherein the decision gate is dependent on reaching a predetermined end of process criterion, where if the end of process criterion is attained, the exemplary process 100 terminates via end of process step 114, whereas if the end of process criterion is not attained then the exemplary process 100 can continue via the cyclical process loop 112 and one or more further deposition cycles can be performed until the end criterion is successfully attained.

In some embodiments, the end criterion for ending the exemplary process 100 may comprises reaching a predetermined thickness of the passivation layer on the first dielectric surface. In some embodiments, the end criterion for ending the exemplary process 100 may comprises performing a predetermined number of deposition cycles.

For example, if the end criterion is not satisfied, then the exemplary process 100 may continue via the cyclical process loop 112 and one or more further deposition cycles may be performed by performing optional process step 104, and process steps 106 and 108.

Therefore, in some embodiments, a deposition cycle may be repeated one or more times until an organic passivation film of a desired thickness is selectively deposited. Such a selective deposition cycle can be repeated until a passivation layer of sufficient thickness is deposited on the first dielectric surface and/or a predetermined number of deposition cycles have been performed. For example, in some embodiments, the exemplary process 100 may comprise, from at least 10 to at most 30,000 deposition cycles, or from at least 10 to at most 3,000 deposition cycles, or from at least 10 to at most 1,000 deposition cycles, or from at least 10 to at most 500 deposition cycles, or from at least 20 to at most 200 deposition cycles, or from at least 50 to at most 150 deposition cycles, or from at least 75 to at most 125 deposition cycles, for example 100 deposition cycles.

The selective deposition cycle can include additional processes (not shown), and need not be in the same sequence nor identically performed in each repetition, and can be readily extended to more complex vapor deposition techniques. For example, a selective cyclical deposition cycle can include additional reactant/precursor supply processes, such as the supply and removal of additional reactants/precursors in each cycle or in selected cycles.

For example, in some embodiments, the substrate is contacted with the first vapor phase organic precursor (step 106) prior to being contacted with the second vapor phase organic precursor (step 108). Thus, in some embodiments the substrate is contacted with an amine, such as a diamine, for example 1,6-diaminohexane (DAH) prior to being contacted with another organic precursor. However, in some embodiments the substrate may be contacted with the second vapor phase organic precursor prior to being contacted with the first vapor phase organic precursor. Thus, in some embodiments the substrate is contacted with an anhydride, such as furan-2,5-dione (maleic acid anhydride), or more particularly, a dianhydride, e.g., pyromellitic dianhydride (PMDA) prior to being contacted with another organic precursor.

In some embodiments, the passivation layer selectively deposited on the first dielectric surface of the substrate may have an average thickness of less than 50 nanometers, or less than 20 nanometers, or less than 10 nanometers, or less than 5 nanometers, or less than 3 nanometers, or less than 2 nanometers, or less than 1 nanometer, or even between 1 nanometer and 50 nanometers.

In some embodiments, the ratio of material deposited on the first dielectric surface relative to the second metallic surface may be greater than or equal to 200:1, or greater than or equal to 100:1, or greater than or equal to 50:1, or greater than or equal to 25:1, or greater than or equal to 20:1, or greater than or equal to 15:1, or greater than or equal to 10:1, or greater than or equal to 5:1, or greater than or equal to 3:1, or greater than or equal to 2:1.

In some embodiments, the selectivity of the methods of present disclosure for selectivity forming a passivation layer on a first dielectric surface relative to the second metallic surface can be greater than 10%, or greater than 50%, or greater than 75%, or greater than 85%, or greater than 90%, or greater than 93%, or greater than 95%, or greater than 98%, or greater than about 99%, or even greater than 99.5%. Therefore, in some embodiments, an organic passivation layer can be deposited preferentially on a first dielectric surface relative to a second metallic surface with a selectivity above 50%.

The embodiments of the present disclosure can also include methods for not only selectively forming a passivation layer a first dielectric surface relative to a second metallic surface on a substrate but can also include methods that utilize said selective passivation layers.

Therefore in some embodiments, methods for selectively forming and utilizing a passivation layer on a substrate are disclosed. For example, the methods can comprising, seating a substrate including a first dielectric surface and a second metallic surface within a reaction chamber, selectively depositing an organic passivation layer on the first dielectric surface relative to the second metallic surface by performing a plurality of deposition cycles of a plasma-free thermal molecular layer cyclical deposition process in which the substrate is alternately and sequentially contacted with a first vapor phase organic precursor, and a second vapor phase organic precursor, wherein one or more of the deposition cycles includes an additional step of contacting the substrate with an additional vapor phase reactant comprising a vapor phase reducing agent, or a vapor phase etchant. The methods can also include, depositing a target film from vapor phase reactants on the second metallic surface.

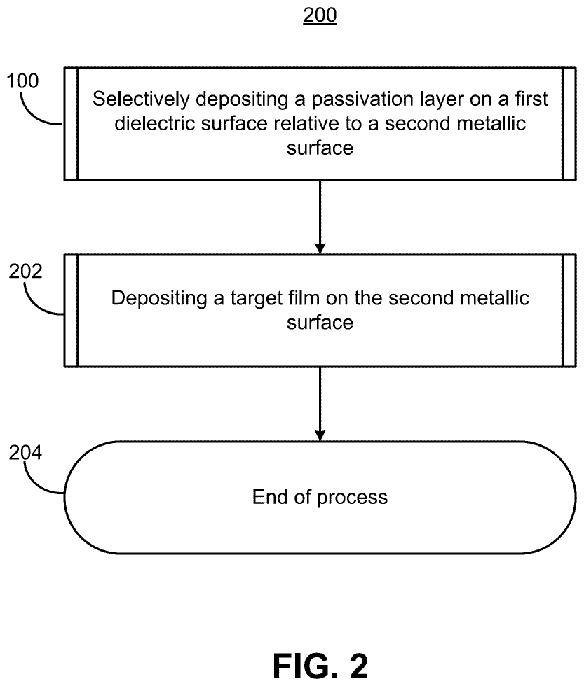

In more detail, FIG. 2 illustrates a second exemplary process 200 that can commence by selectively depositing a passivation layer on a first dielectric surface relative to a second metallic surface (step 100), as previous described herein above with reference to FIG. 1 and exemplary process 100.

In some embodiments, the second exemplary process 200 may continue with a process step 202 comprising, depositing a target film on the second metallic surface. In some embodiments, the target film may comprise a dielectric film thereby enabling a dielectric-on-metal selective process, or the target film may comprise a metal (or metallic) film, thereby enabling a metal-on-metal selective process.

In some embodiments, the target film may be deposited in the same reaction chamber utilized for the formation of the passivation layer or alternatively the substrate may be transferred to a second reaction chamber (e.g., under a controlled atmosphere). In some embodiments, the target film may be deposited by cyclical deposition methods, such as, for example, atomic layer deposition (ALD), or cyclical chemical vapor deposition (CCVD).

In some embodiments, the target film can be deposited by performing a plurality of deposition cycles of a plasma-free thermal cyclical deposition process in which the substrate is alternately and sequentially contacted with a first vapor phase reactant, and a second vapor phase reactant.

Details of process for forming a target film and particular methods for selectively forming a target film on a selective passivation layer are described in detail in the '769 patent and are therefore not repeated herein in interest of brevity. The second exemplary process 200 may conclude once the target film has been deposited to a desired thickness via the end of process step 204.

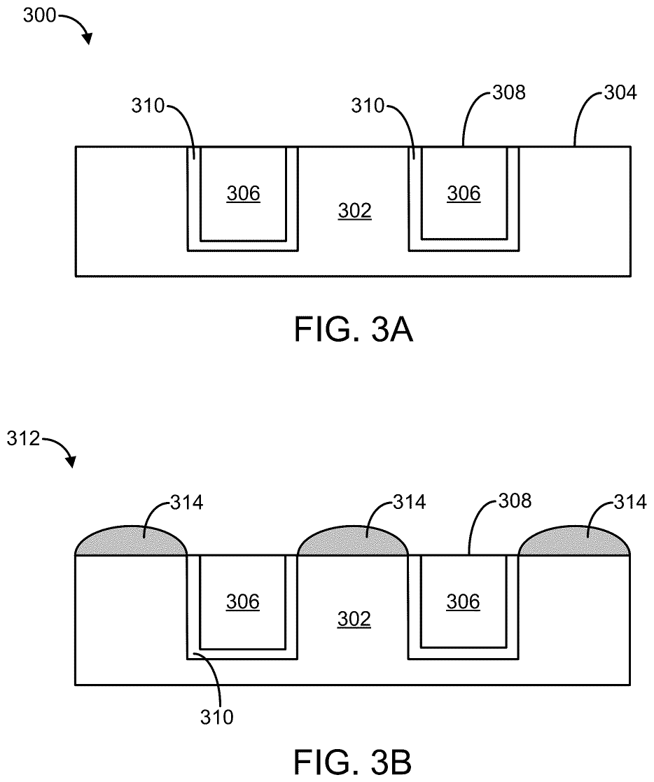

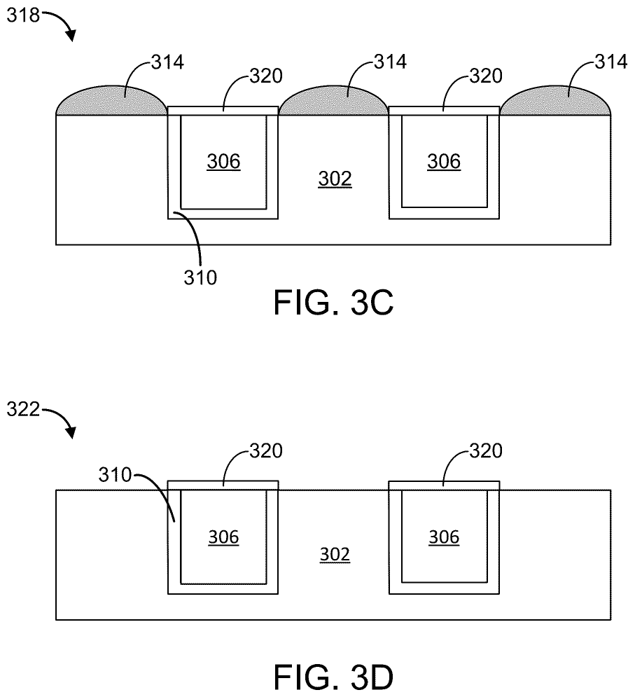

The present disclosure also includes structures formed according to the methods of the present disclosure. For example, FIGS. 3A-D illustrate exemplary cross-sectional views of structures formed by methods of the present disclosure.

In more detail, FIG. 3A illustrates a structure 300 that includes, a dielectric material 302 with a first dielectric surface 304. The dielectric material 302 may comprise, a low-k dielectric material, for example. The structure 300 can also include metallic features 306, such as, copper features, for example. The metallic features 306 can also comprise an exposed second metallic surface 308, such as, a copper surface or a copper oxide surface, for example. The structure 300 can also include metallic barriers 310 which may function as barrier layers to prevent the diffusion of the metallic features 306 into the surrounding dielectric material 302. As a non-limiting example, the barrier layers may comprise a metallic nitride, such as, titanium nitride or molybdenum nitride, or metallic material, such as elemental molybdenum, for example.

FIG. 3B illustrates structure 312 which comprises the structure 300 of FIG. 3A after the selective deposition of the passivation layer on the first dielectric surface 304 relative to the second metallic surface 308 according to methods of the present disclosure. As illustrated in FIG. 3B, the passivation layer 314 is selectively disposed over the dielectric surfaces relative to the metallic surfaces. As a non-limiting example, the passivation film layer 314 may comprise a polyimide film deposited utilizing the selective cyclical deposition process described herein.

FIG. 3C illustrates a structure 318 which comprises a target film 320 disposed directly on the surface of metallic features 306 and on the metallic barrier 310 between the passivation layer 314 disposed over the surface of dielectric material 302. As a non-limiting example, the target film 320 may comprise a metal, a metal oxide film, or a dielectric film deposited utilizing cyclical deposition processes.

FIG. 3D illustrates a structure 322 which demonstrates the structure 318 (FIG. 3C) after the selective removal of the passivation layer while maintaining a thickness of the target film 320 disposed over the and metallic features 306 and the metallic surfaces.

Although certain embodiments and examples have been discussed, it will be understood by those skilled in the art that the scope of the claims extend beyond the specifically disclosed embodiments to other alternative embodiments and/or uses and obvious modifications and equivalents thereof. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

In the present disclosure, where conditions and/or structures are not specified, the skilled artisan in the art can readily provide such conditions and/or structures in view of the present disclosure, as a matter of routine experimentation

What is claimed is:

1. A method for selectively forming a passivation layer on a substrate, the method comprising:
seating a substrate including a dielectric surface and a metallic surface within a reaction chamber; and
selectively depositing a passivation layer on the dielectric surface relative to the metallic surface by performing multiple deposition cycles of a cyclical deposition process in which the substrate is alternately and sequentially contacted with a first vapor phase organic precursor and a second vapor phase organic precursor for forming the passivation layer; and
wherein one or more of the deposition cycles includes an additional step of contacting the substrate with an additional vapor phase reactant comprising a vapor phase reducing agent, or a vapor phase etchant.

2. The method of claim 1, wherein the cyclical deposition process is a plasma-free thermal molecular layer cyclical deposition process.

3. The method of claim 1, wherein the first vapor phase organic precursor comprises a diamine, the second vapor phase organic precursor comprises a dianhydride, and the passivation layer comprises a polyimide.

4. The method of claim 1, wherein the one or more of the deposition cycles include the additional step performed in a sequence comprising:
firstly contacting the substrate with the additional vapor phase reactant comprising the vapor phase reducing agent, or the vapor phase etchant;
secondly contacting the substrate with the first vapor phase organic precursor; and
thirdly contacting the substrate with the second vapor phase organic precursor.

5. The method of claim 1, wherein an initial one of the deposition cycles includes the additional step of contacting the substrate with the additional vapor phase reactant, wherein the additional step is performed prior to contacting the substrate with the first vapor phase organic precursor and prior to contacting the substrate with the second vapor phase organic precursor.

6. The method of claim 1, wherein every deposition cycle includes the additional step of contacting the substrate with the additional vapor phase reactant.

7. The method of claim 1, wherein the additional step is performed prior to contacting the substrate with the first vapor phase organic precursor and prior to contacting the substrate with the second vapor phase organic precursor.

8. The method of claim 1, wherein the additional step is performed after contacting the substrate the second vapor phase organic precursor.

9. The method of claim 1, wherein the vapor phase reducing agent is selected from the group consisting of alcohols, β-diketones, carboxylic acids, amines, aldehydes, boranes, forming gas (H₂+N₂), hydrazine (N₂H₄), hydrazine derivatives, molecular hydrogen (H₂), and atomic hydrogen (H).

10. The method of claim 1, wherein the vapor phase etchant is selected from the group consisting of acetic acid, and hexafluoroacetylacetone (H(hfac)).

11. The method of claim 1, wherein the metallic surface comprises a copper oxide (CuOₓ) surface and contacting the copper oxide (CuOₓ) surface with the additional vapor phase reactant at least partially removes the copper oxide (CuOₓ) surface.

12. The method of claim 1, wherein the metallic surface further comprises an organic residue and contacting the organic residue with the additional vapor phase reactant at least partially removes the organic residue.

13. A structured formed by the method of claim 1.

14. A method for selectively forming and utilizing a passivation layer on a substrate, the method comprising:
seating a substrate including a dielectric surface and a metallic surface within a reaction chamber;
selectively depositing an organic passivation layer on the dielectric surface relative to the metallic surface by performing a plurality of deposition cycles of a plasma-free thermal molecular layer cyclical deposition process in which the substrate is alternately and sequentially contacted with a first vapor phase organic precursor, and a second vapor phase organic precursor, wherein one or more of the deposition cycles includes an additional step of contacting the substrate with an additional vapor phase reactant comprising a vapor phase reducing agent, or a vapor phase etchant; and
depositing a target film from vapor phase reactants on the metallic surface.

15. The method of claim 14, wherein the organic passivation layer is deposited on the dielectric surface relative to the metallic surface with a selectivity above 50%.

16. The method of claim 14, wherein the first vapor phase organic precursor comprises a diamine, the second vapor phase organic precursor comprises a dianyhydride, and the passivation layer comprises a polyimide.

17. The method of claim 14, wherein the one or more of the deposition cycles include the additional step performed in a sequence comprising:
firstly contacting the substrate with the additional vapor phase reactant comprising the vapor phase reducing agent, or the vapor phase etchant;
secondly contacting the substrate with the first vapor phase organic precursor; and
thirdly contacting the substrate with the second vapor phase organic precursor.

18. The method of claim 14, wherein the target film is deposited by performing a plurality of deposition cycles of a plasma-free thermal cyclical deposition process in which the substrate is alternately and sequentially contacted with a first vapor phase reactant, and a second vapor phase reactant.

19. The method of claim 14, wherein the target film comprises a dielectric film or a metallic film.

20. A structure formed according to the method of claim 14.
